(19) United States
(12) Patent Application Publication
(10) Pub. No.: US 2025/0261339 A1
(43) Pub. Date: Aug. 14, 2025

(54) HEAT DISSIPATING DEVICE

(71) Applicant: Samsung Electronics Co., Ltd., Suwon-si (KR)

(72) Inventors: Youngjoon KOH, Suwon-si (KR); Jaechoon KIM, Suwon-si (KR); Jonggyu LEE, Suwon-si (KR)

(73) Assignee: Samsung Electronics Co., Ltd., Suwon-si (KR)

(21) Appl. No.: 18/903,078

(22) Filed: Oct. 1, 2024

(30) Foreign Application Priority Data
Feb. 13, 2024 (KR) 10-2024-0020120

(51) Int. Cl. H05K 7/20

(52) U.S. Cl. CPC H05K 7/20409; H05K 7/2029; H05K 7/20436

(57) ABSTRACT

A heat dissipating device includes a lower case having a partition wall, a plurality of pillars disposed inside the partition wall, and an upper case installed on the partition wall of the lower case and defining an internal space together with the lower case, wherein the internal space defined by the upper case and the lower case is filled with vapor, and the lower case and the upper case include unevenness portions between the plurality of pillars and formed respectively facing the upper case and the lower case.

### CROSS-REFERENCE TO RELATED APPLICATION(S)

This application claims benefit of and priority to Korean Patent Application No. 10-2024-0020120 filed on Feb. 13, 2024 in the Korean Intellectual Property Office, the disclosure of which is incorporated herein by reference in its entirety.

### BACKGROUND

The present inventive concepts relate to heat dissipating devices.

With the advent of the era of artificial intelligence (AI), high-performance computing (HPC), and autonomous vehicles, large-area package products have been produced to mount numerous CPUs and memories in a single package. The large-area package products are mostly high-heat products to which power of 1 kW or higher is applied, and heat solution is a major element of advanced packages.

Meanwhile, in a package process, an assembly process is generally performed in an environment in which temperatures rise above 200° C., such as thermal interface material (TIM) curing, surface mounting technology (SMT), and the like. However, when thermal expansion mismatch occurs, internal thermal resistance between a chip and a TIM may increase, and internal components of packages may be stressed due to warpage, which reduces mechanical stability and deteriorates product performance.

### SUMMARY

An aspect of the present inventive concepts is to provide a heat dissipating device capable of reducing thermal deformation and contact thermal resistance.

Another aspect of the present inventive concepts is to provide a heat dissipating device capable of reducing stress applied to electronic components due to thermal deformation.

According to an aspect of the present inventive concepts, a heat dissipating device includes a lower case having a partition wall, a plurality of pillars inside the partition wall, and an upper case installed on the partition wall of the lower case and defining an internal space together with the lower case, wherein the internal space defined by the upper case and the lower case is filled with vapor, and the lower case and the upper case include unevenness portions between the plurality of pillars and formed respectively facing the upper case and the lower case.

According to an aspect of the present inventive concepts, a heat dissipating device includes a lower case including a base having a rectangular plate shape and a partition wall extending from an upper surface of the base, a plurality of pillars inside the partition wall and on the upper surface of the base, and an upper case coupled to the lower case to define an internal space with the lower case, wherein the internal space defined by the lower case and the upper case is filled with vapor, the lower case and the upper case include unevenness portions between the plurality of pillars, and a lower surface of the base of the lower case and an upper surface of the upper case are configured to be deformed into a flat planar shape in response thermal deformation.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a configuration diagram illustrating a heat dissipating device according to some example embodiments;

FIG. 2 is an exploded perspective view illustrating a heat dissipating device according to some example embodiments;

FIGS. 3 and 4 are diagrams illustrating an operation of a heat dissipating device according to some example embodiments;

FIG. 5 is a configuration diagram illustrating a heat dissipating device according to some example embodiments;

FIG. 6 is an exploded perspective view illustrating a heat dissipating device according to some example embodiments;

FIGS. 7 to 9 are perspective views illustrating pillars of a heat dissipating device according to some example embodiments; and

FIG. 10 is a diagram illustrating an unevenness portion provided in a heat dissipating device according to some example embodiments.

### DETAILED DESCRIPTION

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, example embodiments of the present inventive concepts are described with reference to the accompanying drawings.

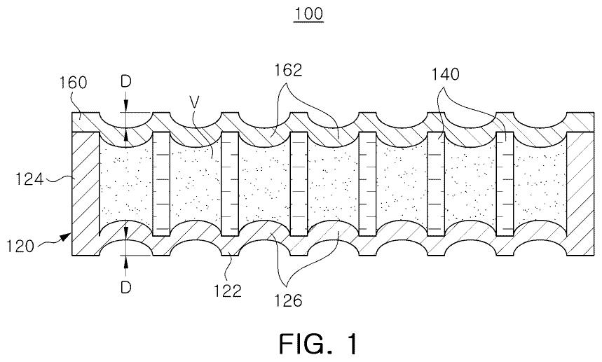

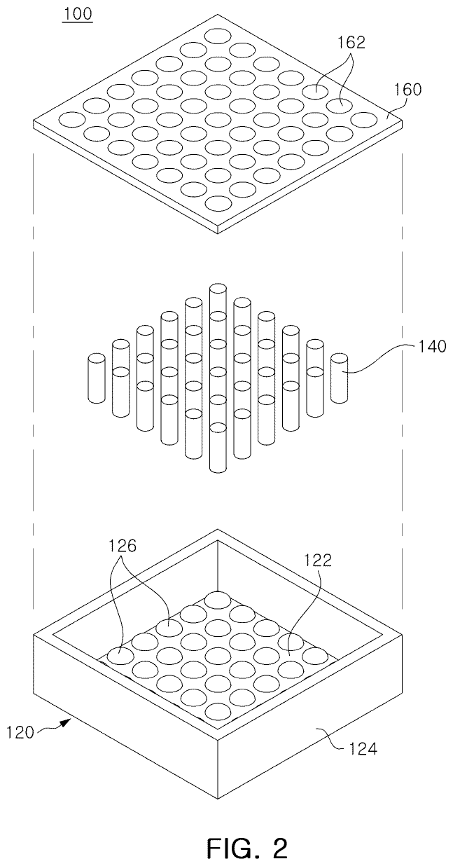

FIG. 1 is a configuration diagram illustrating a heat dissipating device according to some example embodiments, and FIG. 2 is an exploded perspective view illustrating the heat dissipating device according to some example embodiments.

Referring to FIGS. 1 and 2, a heat dissipating device 100 according to some example embodiments includes a lower case 120, a pillar 140, and an upper case 160.

The lower case 120 may include a base 122 having a plate shape, for example a square, and a partition wall 124 extending upwardly from an edge of the base 122. Meanwhile, the lower case 120 may be formed of a metal material. For example, the lower case 120 may be formed of a material including copper. In addition, the base 122 may include a first unevenness portion 126 disposed between the pillars 140 not to interfere with the pillars 140. The first unevenness portion 126 may be formed to be convex toward the upper case 160. In other words, the first unevenness portion 126 may be formed to be concave upwardly from a lower surface of the upper case 160. Meanwhile, a region between the first unevenness portion 126 and the first unevenness portion 126 may have a planar shape. As an example, the first unevenness portion 126 may have a curved shape. Meanwhile, a depth D of the first unevenness portion 126 may be 20 μm to 200 μm. If the depth D of the first unevenness portion 126 is less than 20 μm, a lower surface of the base 122 may be deformed to be convex downwardly during thermal deformation and may not have a flat shape. For example, in some embodiments the first unevenness portion 126 may face the upper case 160. In addition, if the depth D of the first unevenness portion 126 is greater than 200 μm, the lower surface of the base 122 may not have a flat planar shape due to thermal deformation and may become convex toward the upper case 160.

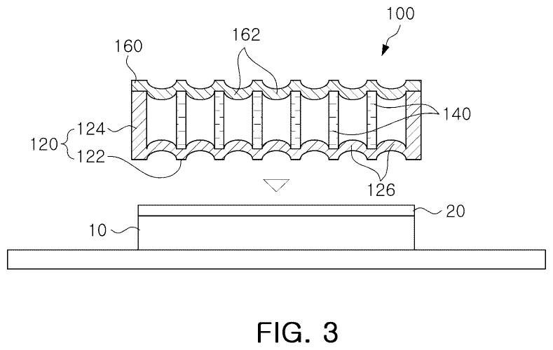

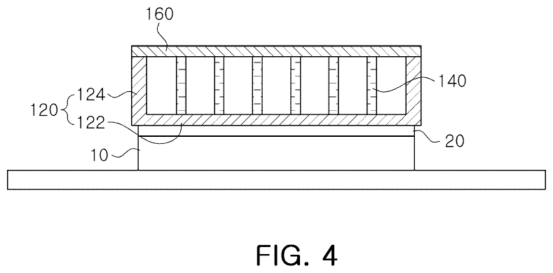

As an example embodiment, the electronic component 10 (see FIGS. 3 and 4) may be bonded to the lower surface of the lower case 120 via a TIM 20 (see FIGS. 3 and 4). Meanwhile, during the process of bonding the heat dissipating device 100 to the electronic component 10 via the TIM 20, the first unevenness portion 126 may be thermally expanded by thermal deformation and deformed flat. For example, during the process of bonding the heat dissipating device 100 to the electronic component 10 via the TIM 20, the first unevenness portion 126 may be thermally expanded such that the lower surface of the first unevenness portion 126 is coplanar with the lower surface of the base 122. Accordingly, the lower surface of the lower case 120 may have a flat planar shape, and thus, contact thermal resistance may be reduced when the lower case 120 comes into contact with the TIM 20. In addition, since stress applied to the electronic component 10 and the risk of warpage due to thermal expansion may be reduced, mechanical stability may be maintained.

A plurality of pillars 140 may be provided inside the partition wall 124. For example, the plurality of pillars 140 may be arranged to be spaced apart from each other in an internal space formed by the lower case 120 and the upper case 160. Meanwhile, the pillar 140 may have a pillar shape, for example a cylindrical shape. Thus, since the pillar 140 has a cylindrical shape, a region on which stress is concentrated may not be formed in the pillar 140. In addition, the pillar 140 may be formed of the same material as that of the lower case 120. Also, the pillar 140 may be formed of a metal material. For example, the lower case 120 may be formed of a material including copper. For example, the pillar 140 may be formed of a material including copper.

The upper case 160 may have a plate shape, for example a rectangular shape. As an example, the upper case 160 may be installed on an upper surface of the partition wall 124 of the lower case 120. Meanwhile, the internal space formed by the upper case 160 and the lower case 120 may be filled with vapor V. For example, the internal space formed by the upper case 160 and the lower case 120 serves as a vapor chamber. Meanwhile, the upper case 160 may be formed of a metal material. For example, the upper case 160 may be formed of a material including copper. In some example embodiments, the upper case 160, the pillar 140, and the lower case 120 may be formed of the same material. In addition, the upper case 160 may include a second unevenness portion 162 disposed between the pillars 140 not to interfere with the pillars 140. The second unevenness portion 162 may be formed to be convex toward the lower case 120. Meanwhile, a region between the second unevenness portion 162 and the second unevenness portion 162 may have a planar shape. As an example, the second unevenness portion 162 may have a curved shape. For example, in some example embodiments, the second unevenness portion 162 may face the lower case 120. Meanwhile, the depth D of the second unevenness portion 162 may be 20 μm to 200 μm. Meanwhile, during the process of installing components, such as a heat sink (not shown), on top of the heat dissipating device 100 via the TIM 20, the second unevenness portion 162 may thermally expand due to thermal deformation to be deformed flat. For example, during the process of installing components, such as a heat sink (not shown), on top of the heat dissipating device 100 via the TIM 20, the second unevenness portion 162 may be thermally expanded such that an upper surface of the second unevenness portion 162 is coplanar with an upper surface of the upper case 160. Accordingly, the upper surface of the upper case 160 may have a flat planar shape, and thus, contact thermal resistance may be reduced when the upper case 160 comes into contact with the TIM 20. In addition, since the stress applied to other components and the risk of warpage due to thermal expansion may be reduced, mechanical stability may be maintained.

FIGS. 3 and 4 are diagrams illustrating an operation of a heat dissipating device according to some example embodiments.

First, referring to FIG. 3, before the heat dissipating device 100 is bonded to the electronic component 10, the first and second unevenness portions 126 and 162 are provided in the lower case 120 and the upper case 160 of the heat dissipating device 100, respectively. Meanwhile, the first unevenness portion 126 of the lower case 120 may be disposed between the pillars 140 not to interfere with the pillars 140. In addition, the first unevenness portion 126 may be formed to be convex toward the upper case 160. In addition, the first unevenness portion 126 may have a curved shape. In addition, the second unevenness portion 162 of the upper case 160 may also be disposed between the pillars 140 not to interfere with the pillars 140. In addition, the second unevenness portion 162 of the upper case 160 may be formed to be convex toward the lower case 120. In addition, the second unevenness portion 162 may have a curved shape.

Thereafter, during the process of bonding the heat dissipating device 100 to the electronic component 10 via the TIM 20, a process temperature may be approximately 150° C. to 250° C. Accordingly, the vapor V filling the internal space formed by the lower case 120 and the upper case 160 is vaporized and the first and second unevenness portions 126 and 162 are thermally deformed. Accordingly, the first and second unevenness portions 126 and 162 may expand and become flat (e.g., coplanar with the bottom surface of the base 122 and the top surface of the upper case 160, respectively). Accordingly, the lower surface of the lower case 120 and the upper surface of the upper case 160 may have a flat planar shape. Accordingly, contact thermal resistance may be reduced when the lower case 120 comes into contact with the TIM 20. In addition, stress applied to the electronic component 10 due to thermal expansion of the lower case 120 and the risk of warpage of the lower case 120 may be reduced, thereby maintaining mechanical stability.

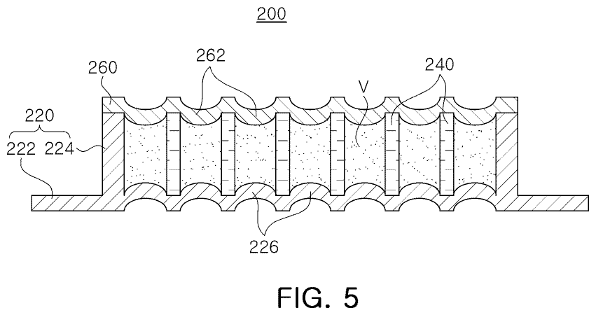

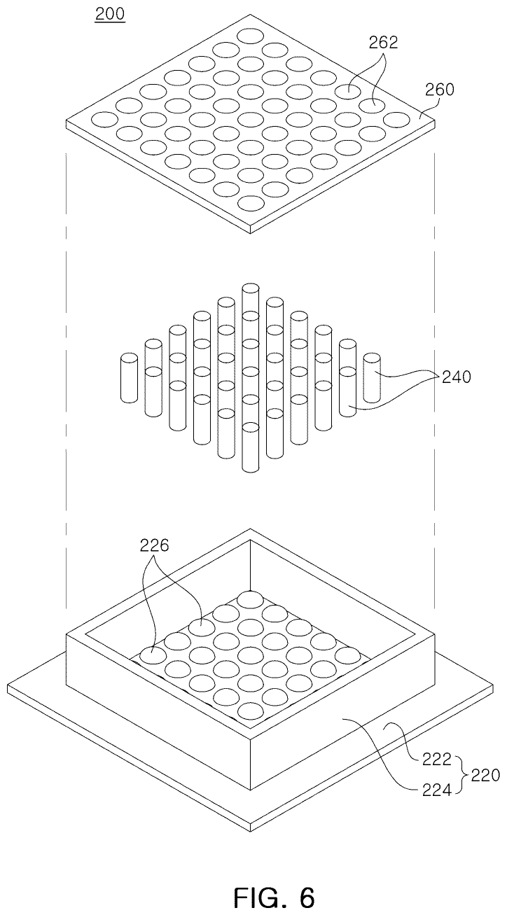

FIG. 5 is a configuration diagram illustrating a heat dissipating device according to some example embodiments, and FIG. 6 is an exploded perspective view illustrating a heat dissipating device according to some example embodiments.

Referring to FIGS. 5 and 6, a heat dissipating device 200 according to some example embodiments include a lower case 220, a pillar 240, and an upper case 260.

Meanwhile, the pillar 240 may include the same component as the pillar 140 described above, and thus, a detailed description thereof is omitted here and replaced with the above description.

The lower case 220 may include a base 222 having a plate shape, for example a square, and a partition wall 224 extending upwardly from an inner edge of the base 222. Meanwhile, the lower case 220 may be formed of a metal material. For example, the lower case 220 may be formed of a material including copper. In addition, the base 222 may include a first unevenness portion 226 disposed between the pillars 240 not to interfere with the pillars 240. The first unevenness portion 226 may be formed to be convex toward the upper case 260. In other words, the first unevenness portion 226 may be formed to be concave from a lower surface of the upper case 260 upwardly. As an example, the first unevenness portion 226 may have a curved shape. Meanwhile, the depth D of the first unevenness portion 226 may be 20 μm to 200 μm. If the depth D of the first unevenness portion 226 is less than 20 μm, the first unevenness portion 226 may be deformed to be convex downwardly during thermal deformation and the lower surface of the base 222 may not have a flat shape. In addition, when the depth D of the first unevenness portion 226 is greater than 200 μm, the lower surface of the base 222 may not have a flat planar shape due to thermal deformation but may be convex toward the upper case.

As an example, the electronic component 10 (see FIGS. 3 and 4) may be bonded to a lower surface of the lower case 220 via the TIM 20 (see FIGS. 3 and 4). Meanwhile, during the process of bonding the heat dissipating device 200 to the electronic component 10 via the TIM 20, the first unevenness portion 226 may be thermally expanded by thermal deformation and deformed flat (e.g., coplanar). For example, during the process of bonding the heat dissipating device 200 to the electronic component 10 via the TIM 20, the first unevenness portion 226 may be thermally expanded such that the lower surface of the first unevenness portion 226 is coplanar with the lower surface of the base 222. Accordingly, the lower surface of the lower case 220 has a flat planar shape, and thus, contact thermal resistance may be reduced when the lower case 220 comes into contact with the TIM 20. In addition, since stress applied to the electronic component 10 and the risk of warpage due to thermal expansion may be reduced, mechanical stability may be maintained.

The upper case 260 may have a plate shape, for example a rectangular shape. In some example embodiments, the upper case 260 may be smaller than the lower case 220. As an example embodiment, the upper case 260 may be installed on an upper surface of the partition wall 224 of the lower case 220. Meanwhile, an internal space formed by the upper case 260 and the lower case 220 may be filled with vapor V. For example, the internal space formed by the upper case 260 and the lower case 220 serves as a vapor chamber. Meanwhile, the upper case 260 may be formed of a metal material. For example, the upper case 260 may be formed of a material including copper. In addition, the upper case 260 may include a second unevenness portion 262 disposed between the pillars 140 not to interfere with the pillars 140. The second unevenness portion 262 may be formed to be convex toward the lower case 220.

As an example, the second unevenness portion 262 may have a curved shape. Meanwhile, the depth D of the second unevenness portion 262 may be 20 μm to 200 μm. Meanwhile, during a process of installing a component, such as a heat sink (not shown), on top of the heat dissipating device 200 via the TIM 20, the second unevenness portion 262 expands due to thermal deformation to be deformed to be flat. For example, during the process of installing components, such as a heat sink (not shown), on top of the heat dissipating device 200 via the TIM 20, the second unevenness portion 262 may be thermally expanded such that an upper surface of the second unevenness portion 262 is coplanar with an upper surface of the upper case 160. Accordingly, the upper surface of the upper case 260 may have a flat planar shape, and thus, contact thermal resistance may be reduced when the upper case 260 comes into contact with the TIM 20. In addition, since stress applied to other components and the risk of warpage due to thermal expansion may be reduced, mechanical stability may be maintained.

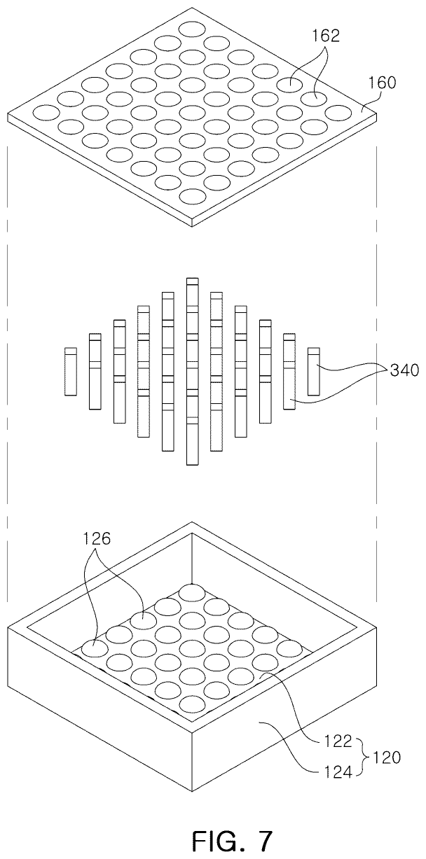

FIGS. 7 to 9 are perspective views illustrating pillars of a heat dissipating device according to some example embodiments.

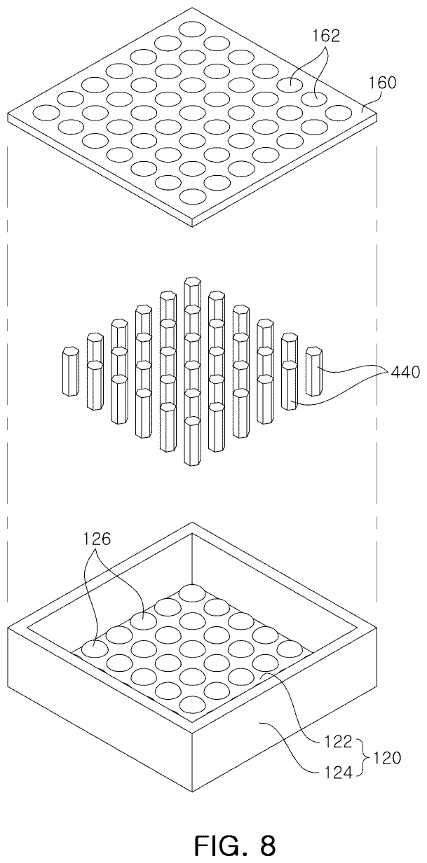

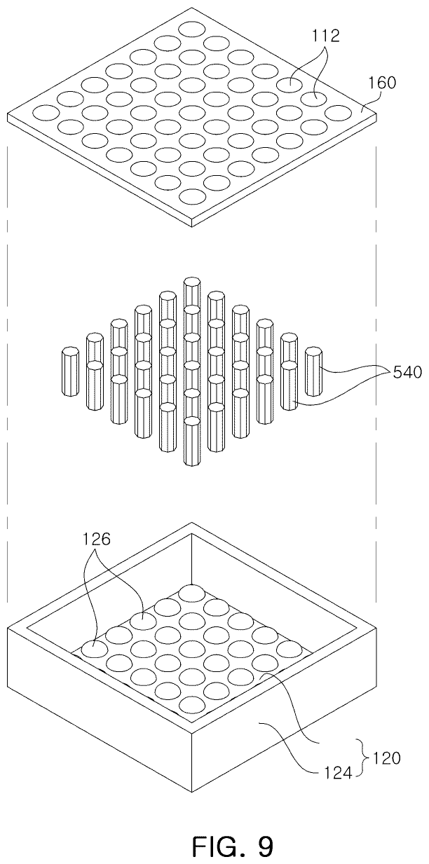

Referring to FIGS. 7 to 9, a plurality of pillars 340, 440, and 540 may be provided inside the partition wall 124. For example, the plurality of pillars 340, 440, and 540 may be arranged to be spaced apart from each other in the internal space formed by the lower case 120 and the upper case 160. Meanwhile, the pillars 340, 440, and 540 may have a polygonal pillar shape. For example, the pillar 340 shown in FIG. 7 may have a square pillar shape, the pillar 440 shown in FIG. 8 may have a hexagonal pillar shape, and the pillar 540 shown in FIG. 9 may have an octagonal pillar shape. However, the shapes of the pillars are not limited thereto and may vary. Meanwhile, the pillars 340, 440, and 540 may be formed of the same material as that of the lower case 120. The pillars 340, 440, and 540 may be formed of a metal material. For example, the pillars 340, 440, and 540 may be formed of a material including copper.

Meanwhile, the lower case 120 and the upper case 160 are substantially the same as the components described above, and thus, a detailed description thereof is omitted here and replaced with the above description.

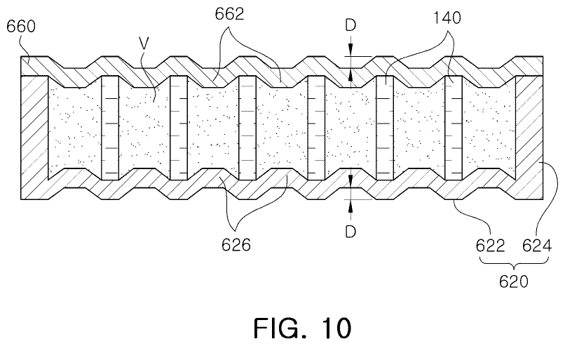

FIG. 10 is a diagram illustrating an unevenness portion provided in a heat dissipating device according to some example embodiments.

Referring to FIG. 10, first and second unevenness portions 626 and 662 provided in a lower case 620 and an upper case 660 may have a trapezoidal cross-section. However, the cross-sectional shape of the first and second unevenness portions 626 and 662 are not limited to the trapezoidal shape may vary. For example, the cross-sectional shape of the unevenness portions may be a triangular or square shape. The first and second unevenness portions 626 and 662 may be formed to be convex toward the upper case 660 and lower case 620, respectively. Meanwhile, the depth D of the first and second unevenness portions 626 and 662 may be 20 μm to 200 μm. In addition, a region between the first unevenness portion 626 and the first unevenness portion 626 may have a planar shape, and a region between the second unevenness portion 662 and the second unevenness portion 662 may also have a planar shape.

Meanwhile, the pillar 140 is substantially the same as the component described above, and thus, a detailed description thereof is omitted here and replaced with the above description.

The heat dissipating device capable of reducing thermal deformation and reducing contact thermal resistance may be provided. As an example, the electronic component 10 (see FIGS. 3 and 4) may be bonded to a lower surface of the lower case 620 via the TIM 20 (see FIGS. 3 and 4). Meanwhile, during the process of bonding the heat dissipating device 600 to the electronic component 10 via the TIM 20, the first unevenness portion 626 may be thermally expanded by thermal deformation and deformed flat (e.g., coplanar). For example, during the process of bonding the heat dissipating device 600 to the electronic component 10 via the TIM 20, the first unevenness portion 626 may be thermally expanded such that the lower surface of the first unevenness portion 626 is coplanar with the lower surface of the base 622. Accordingly, the lower surface of the lower case 620 may have a flat planar shape, and thus, contact thermal resistance may be reduced when the lower case 620 comes into contact with the TIM 20. In addition, since stress applied to the electronic component 10 and the risk of warpage due to thermal expansion may be reduced, mechanical stability may be maintained.

Meanwhile, during a process of installing a component, such as a heat sink (not shown), on top of the heat dissipating device 600 via the TIM 20, the second unevenness portion 662 expands due to thermal deformation to be deformed to be flat. For example, during the process of installing components, such as a heat sink (not shown), on top of the heat dissipating device 600 via the TIM 20, the second unevenness portion 662 may be thermally expanded such that an upper surface of the second unevenness portion 662 is coplanar with an upper surface of the upper case 660. Accordingly, the upper surface of the upper case 660 may have a flat planar shape, and thus, contact thermal resistance may be reduced when the upper case 660 comes into contact with the TIM 20. In addition, since stress applied to other components and the risk of warpage due to thermal expansion may be reduced, mechanical stability may be maintained.

The heat dissipating device capable of reducing stress applied to electronic components due to thermal deformation may be provided.

While example embodiments have been shown and described above, it will be apparent to those skilled in the art that modifications and variations could be made without departing from the scope of the present inventive concept as defined by the appended claims.

What is claimed is:

1. A heat dissipating device comprising:
a lower case having a partition wall;
a plurality of pillars inside the partition wall; and
an upper case installed on the partition wall of the lower case and defining an internal space together with the lower case,
wherein the internal space defined by the upper case and the lower case is filled with vapor, and
the lower case and the upper case include unevenness portions between the plurality of pillars and the unevenness portions facing the upper case and the lower case, respectively.

2. The heat dissipating device of claim 1, wherein the unevenness portion is concavely indented from a lower surface of the lower case toward the upper case.

3. The heat dissipating device of claim 1, wherein the unevenness portion provided in the upper case is convex from a lower surface of the upper case toward the lower case.

4. The heat dissipating device of claim 1, wherein an electronic component is bonded to a lower surface of the lower case via a thermal interface material (TIM).

5. The heat dissipating device of claim 4, wherein the unevenness portion is configured to be deformed by thermal deformation, during a bonding process of the electronic component and the lower case, such that the lower surface of the lower case forms a flat plane in response to the thermal deformation.

6. The heat dissipating device of claim 1, wherein the lower case, the plurality of pillars, and the upper case include a metal material and include a same material.

7. The heat dissipating device of claim 6, wherein the lower case, the plurality of pillars, and the upper case include copper.

8. The heat dissipating device of claim 1, wherein the upper case is smaller than the lower case.

9. The heat dissipating device of claim 1, wherein the plurality of pillars have a cylindrical shape.

10. The heat dissipating device of claim 1, wherein the plurality of pillars have a polygonal pillar shape.

11. The heat dissipating device of claim 1, wherein a depth of the unevenness portion is 20 μm to 200 μm.

12. The heat dissipating device of claim 1, wherein the unevenness portion has a curved cross-section.

13. A heat dissipating device comprising:
a lower case including a base having a plate shape and a partition wall extending from an upper surface of the base;
a plurality of pillars inside the partition wall and on the upper surface of the base; and
an upper case coupled to the lower case to define an internal space with the lower case,
wherein the internal space defined by the lower case and the upper case is filled with vapor,
the lower case and the upper case include unevenness portions between the plurality of pillars, and
a lower surface of the base of the lower case and an upper surface of the upper case are configured to be deformed into a flat planar shape in response to thermal deformation.

14. The heat dissipating device of claim 13, wherein the unevenness portion provided in the lower case is convex toward the upper case.

15. The heat dissipating device of claim 13, wherein the unevenness portion provided in the upper case is convex toward the lower case.

16. The heat dissipating device of claim 13, wherein a depth of the unevenness portion is 20 μm to 200 μm.

17. The heat dissipating device of claim 13, wherein the unevenness portion has a curved cross-section.

18. The heat dissipating device of claim 13, wherein the lower case, the plurality of pillars, and the upper case include a metal material and include a same material.

19. The heat dissipating device of claim 18, wherein the lower case, the plurality of pillars, and the upper case include copper.

20. The heat dissipating device of claim 13, wherein the upper case is smaller than the lower case.
